(19) United States
(12) Patent Application Publication
(10) Pub. No.: US 2008/0093620 A1
(43) Pub. Date: Apr. 24, 2008

(54) LED PACKAGE AND MANUFACTURING METHOD THEREOF

(75) Inventors: Liang-Chih Lee, Hsinchu (TW); Chiao-Chih Yang, Hsinchu (TW); Chien-Min Wang, Hsinchu (TW)

Correspondence Address: J C PATENTS, INC., 4 VENTURE, SUITE 250, IRVINE, CA, 92618, US

(73) Assignee: YOUNG LIGHTING TECHNOLOGY CORPORATION, Hsinchu (TW)

(21) Appl. No.: 11/841,140

(22) Filed: Aug. 20, 2007

(30) Foreign Application Priority Data
Oct. 18, 2006 (TW) 95138336

(51) Int. Cl. H01L 33/00

(52) U.S. Cl. 257/99; 438/26; 257/E33.058

(57) ABSTRACT

A light emitting diode (LED) package including a carrier, an adhering layer and an LED chip is provided. The adhering layer is disposed on the carrier. The LED chip is disposed on the adhering layer and electrically connected to the carrier. The material of the adhering layer comprises a lead-free tin-based eutectic alloy. Furthermore, a manufacturing method for the LED package is provided.

### CROSS-REFERENCE TO RELATED APPLICATION

This application claims the priority benefit of Taiwan application serial no. 95138336, filed Oct. 18, 2006. All disclosure of the Taiwan application is incorporated herein by reference.

### BACKGROUND OF THE INVENTION

1. Field of the Invention

The present invention relates to a light emitting device package, and more particularly to a light emitting diode (LED) package and manufacturing method thereof.

2. Description of Related Art

FIG. 1 is a schematic diagram of a conventional light emitting diode (LED) package. As shown in FIG. 1, the LED package 100 includes a heat slug 110, a first lead 120, a second lead 130, a housing 140, an adhering layer 150, an LED chip 160 and a molding compound 170. The heat slug 110 is disposed between the first lead 120 and the second lead 130 and is electrically connected to the first lead 120. The housing 140 is used for fixing the heat slug 110, the first lead 120 and the second lead 130. The adhering layer 150 is disposed on the heat slug 110 and the LED chip 160 is disposed on the adhering layer 150. Furthermore, the molding compound 170 covers the LED chip 160. In addition, the LED chip 160 is electrically connected to the first lead 120 through the adhering layer 150 and the heat slug 110 and is electrically connected to the second lead 130 through a bonding wire 180. Moreover, the material of the adhering layer 150 is silver epoxy or Au80Sn20 alloy (alloy comprising 80% by weight of gold and 20% by weight of tin).

In the conventional LED package 100, heat produced by the LED chip is transferred to the heat slug 110 via the adhering layer 150 for heat dissipation. When the silver epoxy is used as the adhering material for the adhering layer, because the silver epoxy has a low thermal conductivity (smaller than 20 W/mK), a high coefficient of thermal expansion (greater than 30 ppm/K) and a low adhering strength, therefore, as the heat produced by the LED chip 160 is transferred to the heat slug 110 through the adhering layer 150, the adhering layer 150 will result in an increase in heat resistant and lead to difficulties in heat dissipation. Furthermore, the thermal stress produced by the heat will easily lead to a lowering of the strength of the adhering layer 150 or even damage the adhering layer 150. In addition, after the LED chip 160 is placed on the silver epoxy, the silver epoxy is thermally cured so that the silver epoxy and the LED chip 160 and the heat slug 110 are bonded together. However, the curing process wastes a lot of time and leads to low productivity. Moreover, the adhesive strength of the silver epoxy may vary according to the processing time so that the quality of the silver epoxy after the curing process is not stable.

On the other hand, when the Au80Sn20 alloy is selected as the material forming the adhering layer 150, a high processing temperature of between 300° C. and 330° C. is required to perform the die attaching process. The high processing temperature can easily damage the LED chip 160 so that a special polymer material resistant to high temperature is needed to fabricate the housing 140. Because the Au80Sn20 alloy contains a substantial quantity of gold, the material cost is high. Together with the high cost of the special polymer material, the total cost of fabricating the LED package 100 is rather high.

### SUMMARY OF THE INVENTION

The present invention is directed to a light emitting diode (LED) package that increases heat dissipation efficiency and lowers the production cost.

The present invention is further directed to a manufacturing method for a light emitting diode (LED) package capable of increasing production throughput.

To achieve these and other advantages, as embodied and broadly described herein, the invention provides an LED package comprising a carrier, an adhering layer and an LED chip. The adhering layer is disposed on the carrier. The material of the adhering layer comprises lead-free tin-based eutectic alloy. The LED chip is disposed on the adhering layer and electrically connected to the carrier.

The present invention also provides a manufacturing method of a light emitting diode (LED) package comprising the following steps. First, an adhering body is placed on a carrier and then the adhering body is melted, wherein the material of the adhering body includes lead-free tin-based eutectic alloy. Then, a light emitting diode (LED) chip is placed on the melted adhering body. Thereafter, the LED chip is electrically connected to the carrier.

In the present invention, the material of the adhering layer is lead-free tin-base eutectic alloy, which can lower the heat resistance of the adhering layer during heat transfer and increase heat dissipation efficiency. In addition, the cost of producing the lead-free tin-based eutectic alloy is much lower than that of the Au80Sn20 alloy so that cost may be substantially reduced. Moreover, the method of fabricating the LED package in the present invention does not require a silver epoxy curing process and the maximum surrounding temperature in the processing is between 220° C. and 260° C. Hence, the present invention can increase both the throughput and yield.

Other objectives, features and advantages of the present invention will be further understood from the further technology features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a conventional LED package.

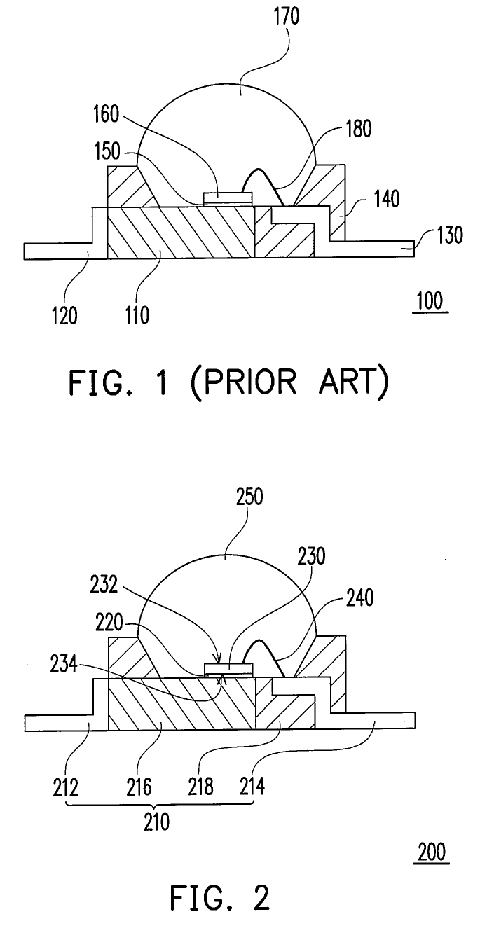

FIG. 2 is a schematic diagram of an LED package according to an embodiment of the present invention.

FIG. 3 is a schematic diagram of an LED package according to another embodiment of the present invention.

FIGS. 4A through 4E are diagrams showing the steps for fabricating an LED package according to an embodiment of the present invention.

### DESCRIPTION OF THE PREFERRED EMBODIMENTS

It is to be understood that other embodiments may be utilized and structural changes may be made without departing from the scope of the present invention. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” and “coupled,” and variations thereof herein are used broadly and encompass direct and indirect connections, couplings, and mountings.

Reference will now be made in detail to the present preferred embodiments of the invention, examples of which are illustrated in the accompanying drawings. Wherever possible, the same reference numbers are used in the drawings and the description to refer to the same or like parts.

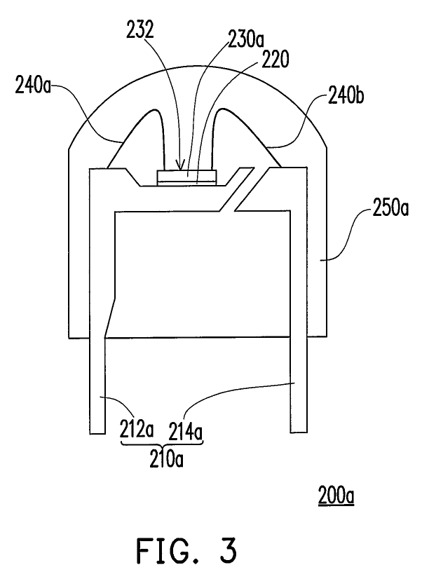

FIG. 2 is a schematic diagram of a light emitting diode (LED) package according to an embodiment of the present invention. As shown in FIG. 2, the LED package 200 in the present embodiment includes a carrier 210, an adhering layer 220 and an LED chip 230. The adhering layer 220 is disposed on the carrier 210. The LED chip 230 is disposed on the adhering layer 220 and is electrically connected to the carrier 210. In addition, a material of the adhering layer 220 includes lead-free tin-based eutectic alloy.

The carrier 210 includes a first lead 212, a second lead 214, a heat slug 216 and a housing 218, for example. The heat slug 216 is disposed between the first lead 212 and the second lead 214 and the first lead 212 is connected to the heat slug 216. The adhering layer 220 is disposed on the heat slug 216. The housing 218 fixes the first lead 212, the second lead 214 and the heat slug 216. The LED chip 230 is electrically connected to the first lead 212 through the adhering layer 220 and the heat slug 216 and is electrically connected to the second lead 214 through a bonding wire 240. In addition, the LED package 200 may further include a molding compound 250 that covers the LED chip 230. The molding compound 230 is fabricated from a transparent material such as epoxy or silicone. The molding compound 230 protects the LED chip 230 and functions as a lens. Furthermore, the lead-free tin-based eutectic alloy is tin-zinc alloy, tin-bismuth alloy, tin-silver alloy, tin-silver-copper alloy, tin-silver-copper-antimony alloy, tin-silver-copper-germanium alloy or tin-silver-copper-indium alloy, for example.

The LED chip 230 (for example: a blue or green LED chip) in FIG. 2 has a top surface 232 and an opposing bottom surface 234, each of which has a contact pad (not shown) disposed thereon. Hence, the contact pad on the bottom surface 234 is electrically connected to the first lead 212 through the adhering layer 220 and the heat slug 216. However, when the two contact pads are located on the top surface 232 of the LED chip 230, for example: a red LED chip, the LED chip 230 can be electrically connected to the first lead 212 and the second lead 214 using two bonding wires 240.

In the present embodiment, the lead-free tin-based eutectic alloy has a thermal conductivity higher than silver epoxy. A tin-silver-copper alloy is taken as an example; its thermal conductivity is as high as 58 W/mK. When the heat produced by the LED chip 230 is transferred through the adhering layer 220 to the heat slug 216, the thermal resistance resulting from the adhering layer 220 is lower. Therefore, the heat dissipation efficiency of the LED package 200 in the present embodiment is higher and then the light emitting efficiency of the LED chip 230 increases. In addition, the adhesive strength of the lead-free tin-based eutectic alloy is higher while the coefficient of thermal expansion is lower. A tin-silver-copper alloy is taken as an example; its coefficient of thermal expansion is smaller than 29 ppm/K so that it is resistant to a higher thermal stress and therefore prevents the lowering of the thermal strength of the adhering layer 220 or the destruction of the adhering layer 220. In addition, the lead-free tin-based eutectic alloy is easier to obtain and the material cost is lower. Thus, the production cost of the LED package 200 is reduced.

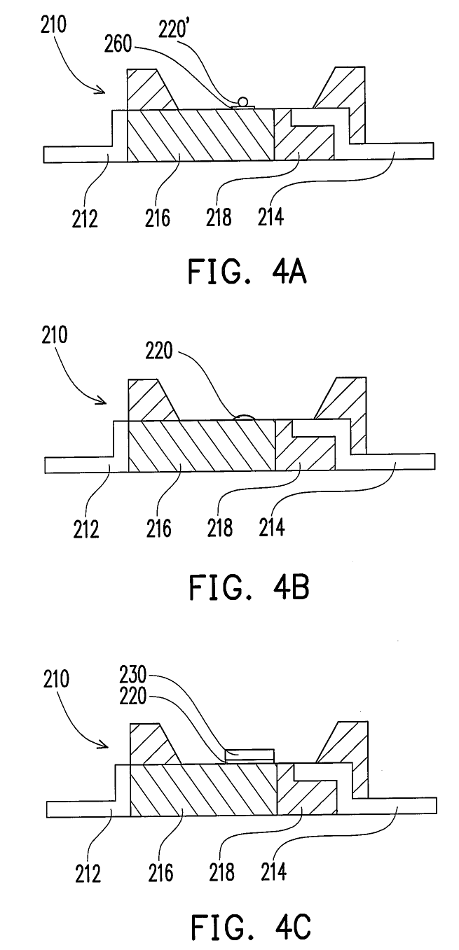

FIG. 3 is a schematic diagram of an LED package according to another embodiment of the present invention. As shown in FIG. 3, the package structure 200a in the present embodiment includes a carrier 210a, an adhering layer 220 and an LED chip 230a. The adhering layer 220 is disposed on the carriers 210a. The LED chip 230 is disposed on the adhering layer 220 and electrically connected to the carrier 210a. More specifically, the carrier 210a includes a first lead 212a and a second lead 214a and the adhering layer 220 is disposed on the first leads 212a. The two contact pads (not shown) of the LED chip 230a are located on the top surface 232, for example. One of the contact pads is electrically connected to the first lead 212a through a bonding wire 240a while the other contact pad is electrically connected to the second lead 214a through another bonding wire 240b. In addition, the LED package 200a further includes a molding compound 250a that encapsulates part of the carrier 210a, the bonding wires 240a and 240b, the LED chip 230a and the adhering layer 220.

The material and function of the adhering layer 220 and the molding compound 250a in the foregoing LED package 200a are similar to that of the adhering layer 220 and the molding compound 250 in the LED package 200. The advantages of the LED packages 200 and 200a are also similar. Thus, a detailed description thereof will not be repeated.

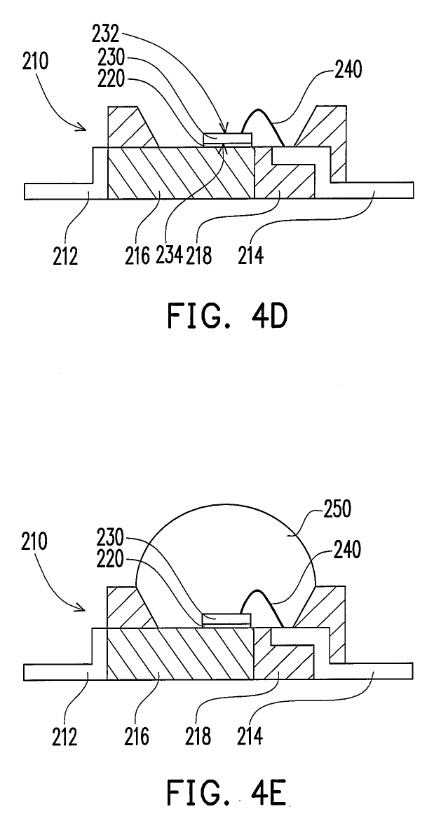

In the following, the manufacturing method of the LED package in FIG. 2 is described. FIGS. 4A through 4E are diagrams showing the steps for fabricating an LED package according to an embodiment of the present invention. The method of manufacturing the LED package in the present embodiment includes the following steps. First, as shown in FIG. 4A, an adhering body 220′ is placed on the heat slug 216 of the carrier 210. The material of the adhering body 220′ includes lead-free tin-based eutectic alloy. The adhering body 220′ can have a spherical-shape body with a diameter between about 0.1 mm and 0.6 mm, for example. This spherical-shape body is tin-zinc alloy, tin-silver alloy, tin-silver-copper alloy, tin-silver-copper-antimony alloy, tin-silver-copper-germanium alloy or tin-silver-copper-indium alloy, for example. Furthermore, the method of placing the adhering body 220′ on the carrier 210 includes performing a ball planting process to place the adhering body 220′ on the heat slug 216. Moreover, flux 260 may be deposited on the heat slug 216 before the step of placing the adhering body 220′ on the heat slug 216. Thereafter, the adhering body 220′ is placed on the flux 260.

It should be noted that the adhering body in the present embodiment could be a paste. Hence, a dotting or a printing process can be used to place the paste on the heat slug 216. The paste is tin-bismuth alloy, tin-zinc alloy, tin-silver alloy, tin-silver-copper alloy, tin-silver-copper-antimony alloy, tin-silver-copper-germanium alloy or tin-silver-copper-indium alloy, for example.

Next, as shown in FIG. 4B, a die attaching process is performed. First, the adhering body 220′ is melted. The step of melting the adhering body 220′ includes heating and melting the adhering body 220′ using a heating plate (not shown) underneath the carrier 210. Furthermore, if flux 260 is also used, the flux 260 will also melted in this step. The melted adhering body 220′ and the flux 260 are mixed together to form an adhering layer 220. It should be noted that a lead-free tin-based eutectic alloy is used as the adhering body 220′ so that the adhering body 220′ only has to be heated to a temperature between 220° C. and 260° C. in order to melt. Thus, comparatively less expensive polymer material can be used to fabricate the housing 218. Next, as shown in FIG. 4C, the LED chip 230 is placed on the adhering layer 220. More specifically, the present embodiment uses a die bonding machine to perform the die attaching process for attaching the LED chip 230 to the adhering layer 220. Because the surrounding temperature is only between 220° C. and 260° C. in the die attaching process, damage to the LED chip 230 is minimized and the yield is increased. In addition, there is no need to cure the adhering layer 220 after the die attaching process because the adhering layer 220 is a lead-free tin-based eutectic alloy. Thus, compared with the conventional technique of using silver epoxy as the adhering layer, the method of manufacturing LED package in the present embodiment is capable of increasing the production throughput.

After the die attaching process is completed, the LED chip 230 is electrically connected to the carrier 210 as shown in FIG. 4D. More specifically, the present embodiment uses a wire bonding method such that the contact pad (not shown) on the top surface 232 of the LED chip 230 is electrically connected to the second lead 214 through a bonding wire 240. The contact pad (not shown) on the bottom surface 234 of the LED chip 230 is electrically connected to the first lead 212 through the adhering layer 220 and the heat slug 216.

As shown in FIG. 4E, after the LED chip 230 is electrically connected to the carrier 210, a molding compound 250 covering the LED chip 230 is formed. The method of forming the molding compound 250 includes coating a layer of a compound and then the compound is cured to form the required shape.

It should be noted that the method of manufacturing the LED package 200a in FIG. 3 is identical to the method of manufacturing the LED package 200 in FIG. 2. Since those skilled in the art is able to deduce the method of manufacturing the LED package 200a by referring to the foregoing description, a detailed description is omitted.

In summary, the LED package and manufacturing method of the present invention has at least the following advantages:

1. The material of the adhering layer comprises lead-free tin-based eutectic alloy, which is capable of lowering the heat resistance in the adhering layer during heat transfer and increasing heat dissipation efficiency.

2. Since the lead-free tin-based eutectic alloy has a higher adhesive strength and a lower coefficient of thermal expansion, it can tolerate a higher thermal stress and prevent the lowering of the strength of the adhering layer or the destruction of the adhering layer due to thermal stress.

3. The lead-free tin-based eutectic alloy is less expensive than the Au80Sn20 alloy. Furthermore, the cost of the polymer material is also lower than that of the special polymer material with high temperature resistant. Therefore, production cost can be effectively reduced.

4. There is no need to cure the adhering layer after the die attaching process. Thus, throughput is increased.

5. The surrounding temperature in the process is only between 220° C. and 260° C. and therefore damage to the LED chip is avoided and the throughput can be increased.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A light emitting diode (LED) package, comprising:
a carrier;
an adhering layer, disposed on the carrier, a material of the adhering layer comprising a lead-free tin-based eutectic alloy; and
a light emitting diode (LED) chip, disposed on the adhering layer and electrically connected to the carrier.

2. The LED package of claim 1, wherein the lead-free tin-based eutectic alloy is selected from a group consisting of tin-bismuth alloy, tin-zinc alloy, tin-silver alloy, tin-silver-copper alloy, tin-silver-copper-antimony alloy, tin-silver-copper-germanium alloy and tin-silver-copper-indium alloy.

3. The LED package of claim 1, wherein the carrier comprises:
a first lead;
a second lead;
a heat slug, disposed between the first lead and the second lead and connected to the first lead, wherein the adhering layer is disposed on the heat slug, and the LED chip is electrically connected to the first lead and the second lead; and
a housing for fixing the first lead, the second lead and the heat slug.

4. The LED package of claim 3, further comprising a bonding wire for connecting between the LED chip and the second lead.

5. The LED package of claim 1, wherein the carrier comprises:
a first lead, the adhering layer disposed on the first lead; and
a second lead, the LED chip electrically connected to the first lead and the second lead.

6. The LED package of claim 5, further comprising a bonding wire for connecting between the LED chip and the second lead.

7. The LED package of claim 1, further comprising a molding compound for covering the LED chip.

8. A manufacturing method of a light emitting diode (LED) package, comprising:
placing an adhering body on a carrier and melting the adhering body, wherein a material of the adhering body comprises lead-free tin-based eutectic alloy;
placing a light emitting diode (LED) chip on the melted adhering body; and
electrically connecting the LED chip to the carrier.

9. The manufacturing method of claim 8, wherein the adhering body is a spherical body, and the step of placing the adhering body on the carrier comprises performing a ball planting process to place the adhering body on the carrier.

10. The manufacturing method of claim 9, further comprising disposing flux on the carrier and then placing the adhering body on the flux before the step of placing the adhering body on the carrier.

11. The manufacturing method of claim 9, wherein the lead-free tin-based eutectic alloy is selected from the group consisting of tin-zinc alloy, tin-silver alloy, tin-silver-copper alloy, tin-silver-copper-antimony alloy, tin-silver-copper-germanium alloy and tin-silver-copper-indium alloy.

12. The manufacturing method of claim 8, wherein the adhering body is a paste, and the step of placing the adhering body on the carrier comprises performing a dotting or printing process to place the adhering body on the carrier.

13. The manufacturing method of claim 12, wherein the lead-free tin-based eutectic alloy is selected from the group consisting of tin-bismuth alloy, tin-zinc alloy, tin-silver alloy, tin-silver-copper alloy, tin-silver-copper-antimony alloy, tin-silver-copper-germanium alloy and tin-silver-copper-indium alloy.

14. The manufacturing method of claim 8, wherein the step of melting the adhering body comprises heating the adhering body to a temperature between about 220° C. and 260° C.

15. The manufacturing method of claim 8, wherein the carrier comprises a first lead, a second lead, and a heat slug, and the first lead is connected to the heat slug and the step of placing the adhering body on the carrier comprises placing the adhering body on the heat slug.

16. The manufacturing method of claim 15, wherein the step of electrically connecting the LED chip to the carrier comprises connecting a bonding wire between the second lead and the LED chip.

17. The manufacturing method of claim 8, wherein the carrier comprises a first lead and a second lead, and the step of placing the adhering body on the carrier comprises placing the adhering body on the first lead.

18. The manufacturing method of claim 17, wherein the step of electrically connecting the LED chip to the carrier comprises connecting a bonding wire between the second lead and the LED chip.

19. The manufacturing method of claim 8, further comprising forming a molding compound covering the LED chip.
